(19) United States
(12) Patent Application Publication
(10) Pub. No.: US 2019/0189467 A1
(43) Pub. Date: Jun. 20, 2019

(54) Structure of printed circuit board and carrier and method of making semiconductor package

(71) Applicant: CHUNG-PAO WANG, Taichung City (TW)

(72) Inventor: CHUNG-PAO WANG, Taichung City (TW)

(21) Appl. No.: 16/224,781

(22) Filed: Dec. 18, 2018

(30) Foreign Application Priority Data
Dec. 18, 2017 (TW) 106144458
Mar. 8, 2018 (TW) 107107905
Mar. 14, 2018 (TW) 107108696
Oct. 9, 2018 (TW) 107135483
Oct. 23, 2018 (TW) 107137405

(51) Int. Cl. H01L 21/48; H01L 23/552; H01L 21/683; H01L 23/498

(52) U.S. Cl. CPC H01L 21/4853; H01L 23/552; H01L 21/481; H01L 21/6835; H01L 24/48; H01L 23/49838; H01L 2221/68345; H01L 2221/68381; H01L 2221/68377; H01L 23/49816

(57) ABSTRACT

A structure of a printed circuit board and a carrier is coupled with a chip, and the printed circuit board contains: a trace, and a dielectric layer. The carrier includes at least an element. The trace at least includes a terminal; the trace has an upper surface, a lower surface, and a side edge, the dielectric layer includes a predetermined opening, an upper surface, a lower surface, and a side edge, wherein the predetermined opening is formed by a portion of the dielectric layer and corresponds to the terminal of the trace. And the carrier is coupled with the dielectric layer.

### FIELD OF THE INVENTION

The present invention relates to a structure of a printed circuit board and a carrier and a method of making a semiconductor package which are applicable for a semiconductor chip.

### DESCRIPTION OF THE PRIOR ART

With reference to FIGS. 14-1 to 14-4 show a method of manufacturing a semiconductor package. Referring to FIG. 14-1, a conventional printed circuit board 5A and a detachable carrier 8K are provided, wherein the printed circuit board 5A includes an insulator 4H and a trace 35 configured to transmit electricity, and the insulator 4H includes an upper surface 41, a lower surface 42, and a via 44. The trace 35 includes an upper surface 31, a lower surface 32, and a side edge 33, wherein the trace 35 is located on the lower surface 42 of the insulator 4H, and the lower surface 32 and the side edge 33 are connected with the insulator 4H, wherein a portion of the lower surface 32 exposing to the via 44 is a contact 324 configured to be externally electrical connection, the upper surface 31 exposes to the lower surface 42 of the insulator 4H, a thickness T of the insulator 4H is comprised of a thickness T4 between the upper surface 41 and the lower surface 32 of the trace 35 and a thickness T3 of the trace 35, wherein a thickness T3 of the trace 35 is within 15 μm to 30 μm, the carrier 8K is comprised of a copper clad laminate 8A, a prepreg 8B, and a detachable cooper foil 8C, wherein the copper clad laminate 8A is comprised of two copper foils 8A1 and adhesive mean 8A2, and the adhesive mean 8A2 is comprised of prepreg or the like so as to connect with the two copper foils 8A1, and the adhesive mean 8A2 is defined between the copper foils 8A1. The detachable cooper foil 8C is comprised of two copper foils and a film layer (such as a release layer or the like; not shown), the film layer is applied to connect with the two copper foils, wherein one of the two copper foils is employed as a the coupling layer 8C1, and the other copper foil is employed as a detachable layer 8C2. The detachable layer 8C2 is connected with the copper clad laminate 8A by using the prepreg 8B, the coupling layer 8C1 and the detachable layer 8C2 are comprised of copper layer and/or other metal layer, and the carrier 8K is located on the lower surface 42 of the insulator 4H, the coupling layer 8C1 is coupled with the lower surface 42 of the insulator 4H of the printed circuit board 5A so that upper surface 31 of the trace 35 is not exposed to the atmosphere, and the chip 20 is provided, and the conductive element 18 is employed as a wire. The chip 20 is located on the upper surface 41 of the insulator 4H, and the conductive element 18 is connected with the pad 24 of the chip 20 and the contact 324 of the trace 30 so that the chip 20 is electrically connected with the printed circuit board 5A. In addition, the encapsulant 60 seals the chip 20, the conductive element 18, and the printed circuit board 5A, thus finishing the semiconductor package 1A. As shown in FIG. 14-2, in a detaching process, the coupling layer 8C1 of the carrier 8K is removed from the detachable layer 8C2, then the detachable layer 8C2, the prepreg 8B, and the copper clad laminate 8A are all removed. The etching solution is employed in the detaching process. With reference to FIG. 14-3 which is a bottom view of the conventional semiconductor package 1A, an etching manner is applicable in the detaching process, then, the coupling layer 8C1 of the detachable copper foil is removed so that the upper surface 31 of the trace 35 exposes to the lower surface 42 of the insulator 4H. Referring to FIG. 14-4, a solder ball S is connected with the upper surface 31 of the trace 35 so that the chip 20 is for externally electrical connection through the solder ball S.

However, the printed circuit board 5A has following defects:

(1). Referring to FIG. 14-4, the thickness T3 of the trace 35 is larger than 15 μm usually, and the trace 35 is coupled with the solder ball S. When the solder ball S is impacted by an external force such as a collision, it is east to cause a delamination or a gap G between the lower surface 32 of the trace 35 and the insulator 4H, so a power and/or a signal(s) transmission between the trace 35 and the conductive element 18 is not stable and/or is caused to an open-circuit problem, and it is easy to damage the semiconductor package 1A. For solving the problems mentioned-above, a thicker thickness T3 of the trace 35 is hired, for examples, the thickness of the trace 35 is equal to or is more than 22 μm so as to enhance a connection area and strength of the side edge 33, thus avoiding the gap G of the semiconductor package 1A. However, the thickness T of the insulator 4H cannot be reduced because the trace 35 is thicker and fabrication cost of the printed circuit board 5A is increased. In addition, the printed circuit board 5A cannot be thinned.

(2). as illustrated in FIG. 14-2, when the coupling layer 8C1 is eliminated by the etching solution, and a portion of the trace 35 is removed simultaneously. The thickness T3 of the trace 35 is transformed into a thinner thickness T3k, so the connection area of the side edge 33 of the trace 35 and the insulator 4H is reduced to decrease the connection strength of the trace 35 and the insulator 4H, and after the trace 35 is coupled with the solder ball S, the solder ball S is impacted by an external force F, and the printed circuit board 5A is broken easily.

The present invention has arisen to mitigate and/or obviate the afore-described disadvantages.

### SUMMARY OF THE INVENTION

The primary objective of the present invention is to provide a structure of a printed circuit board and a carrier, and a method of manufacturing a semiconductor package, wherein the printed circuit board contains at least a trace and a dielectric layer, the carrier contains at least an element, wherein the dielectric layer includes a predetermined opening corresponding to the trace, and the predetermined opening enables to be transferred to be an opening which is penetrated through the dielectric layer, while manufacturing a semiconductor package, in order that the upper surface of the trace can be exposed to the opening for externally electrical connection, the lower surface of the dielectric layer is coupled with the upper surface of the trace, and the upper surface of the dielectric layer is coupled with the lower surface of the carrier, wherein the dielectric layer seals the upper surface of the trace, such that the trace is not etched by the etching solution configured to eliminate the carrier, thus avoiding damage of the trace.

Preferably, due to the lower surface of the carrier enables to be coupled with the dielectric layer, and the dielectric layer is defined between the trace and the carrier. The dielectric layer includes the predetermined opening which does not pass through the dielectric layer to enhance the rigidity of the structure of the printed circuit board and the carrier and to avoid bending and/or breaking the structure of the printed circuit board and the carrier.

Furthermore, the printed circuit board includes an insulator as required, and the dielectric layer is defined between the carrier, the trace, and the insulator, thus more enhancing the rigidity of the structure of the printed circuit board and the carrier and avoiding the bending and/or breaking of the structure of the printed circuit board and the carrier. The insulator further has a via, and the printed circuit board further selectively enables to include a second trace to enhance the trace density of the printed circuit board, and the carrier also can be for the electromagnetic shielding to enhance resistance of the semiconductor package against the electromagnetic interference.

Preferably, the carrier enables not to contain the detachable copper foils of the conventional carrier to reduce the fabrication cost and to thin the printed circuit board and the carrier, thus enhancing the quality of the structure of the printed circuit board and the carrier. Meanwhile, the trace also enables to have a protruded portion.

### BRIEF DESCRIPTION OF THE DRAWINGS

FIG. 1-1 is a cross-sectional view of a structure of a printed circuit board and a carrier taken along the line K-K of FIG. 1-2 according to a preferred embodiment of the present invention.

FIG. 1-2 is a bottom plan view of a structure of a printed circuit board according to the preferred embodiment of the present invention.

FIG. 2 is a cross-sectional view of the structure of the printed circuit board and the carrier according to another preferred embodiment of the present invention.

FIG. 3 is a cross-sectional view of the structure of the printed circuit board and the carrier according to another preferred embodiment of the present invention.

FIG. 3A is a cross-sectional view of the structure of the printed circuit board and the carrier according to another preferred embodiment of the present invention.

FIG. 4 is a cross-sectional view of the structure of the printed circuit board and the carrier according to another preferred embodiment of the present invention.

FIG. 5 is a cross-sectional view of the structure of the printed circuit board and the carrier according to another preferred embodiment of the present invention.

FIG. 6 is a cross-sectional view of the structure of the printed circuit board and the carrier according to another preferred embodiment of the present invention.

FIG. 7 is a cross-sectional view of the structure of the printed circuit board and the carrier according to another preferred embodiment of the present invention.

FIG. 8 is a cross-sectional view of the structure of the printed circuit board and the carrier according to another preferred embodiment of the present invention.

FIGS. 9-1 to 9-4 are cross sectional views showing a method of manufacturing a semiconductor package according to another preferred embodiment of the present invention.

FIGS. 10-1 to 10-5 are cross sectional views showing a manufacturing method of a semiconductor package according to another preferred embodiment of the present invention.

FIGS. 11-1 to 11-3 are cross sectional views showing a manufacturing method of a semiconductor package according to another preferred embodiment of the present invention.

FIGS. 12-1 to 12-3 are cross sectional views showing a manufacturing method of a semiconductor package according to another preferred embodiment of the present invention.

FIGS. 13-1 to 13-4 are cross sectional views showing a manufacturing method of a semiconductor package according to another preferred embodiment of the present invention.

FIGS. 14-1 to 14-4 are cross sectional views showing a manufacturing method of a conventional semiconductor package.

### DETAILED DESCRIPTION OF THE PREFERRED EMBODIMENTS

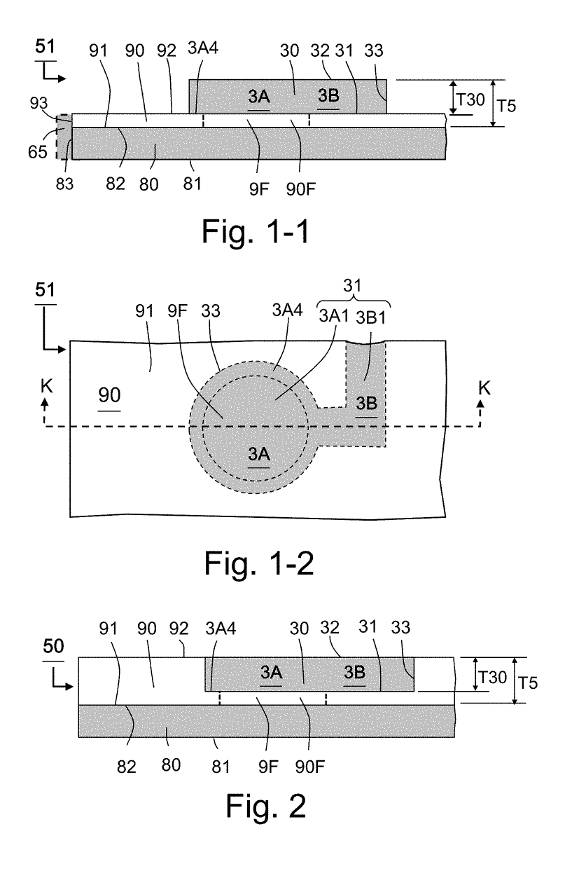

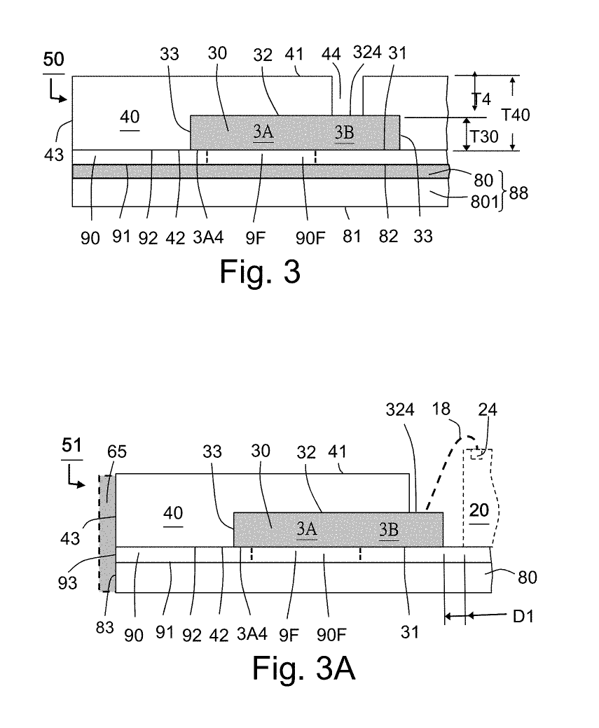

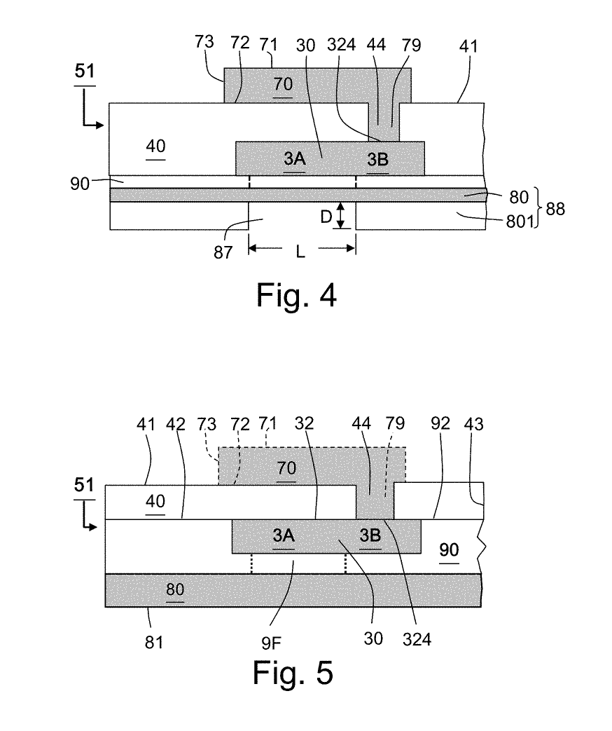

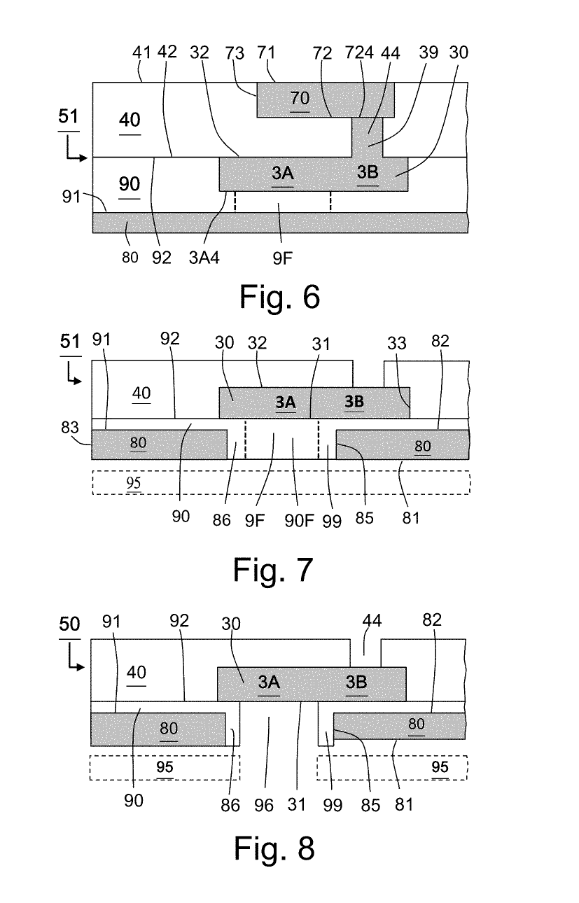

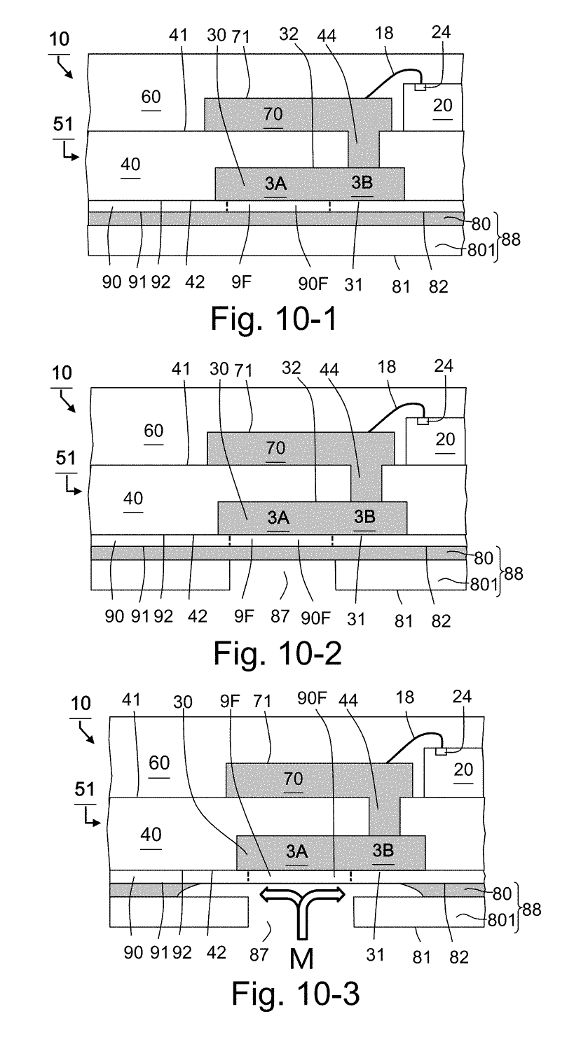

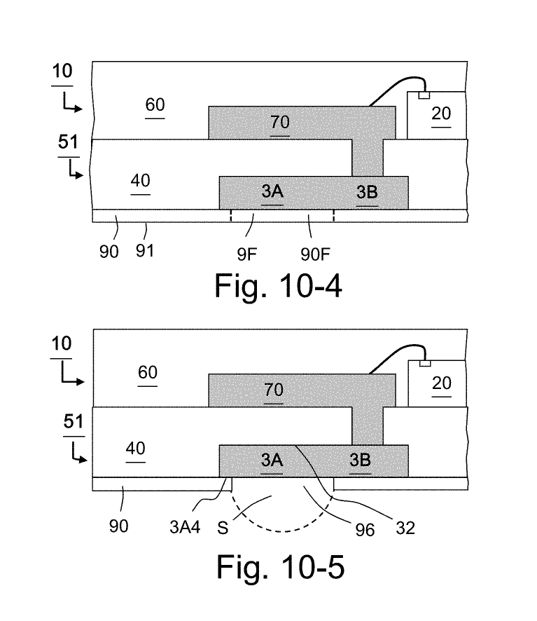

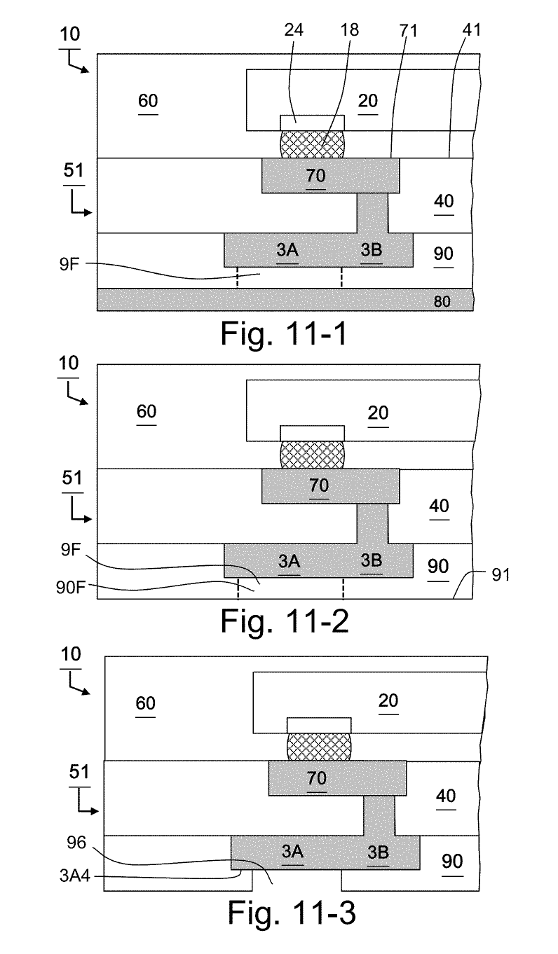

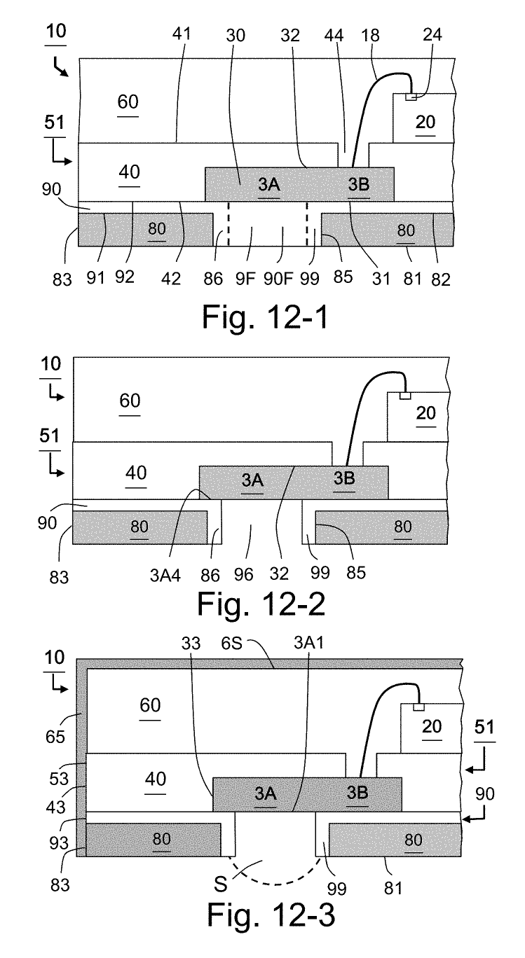

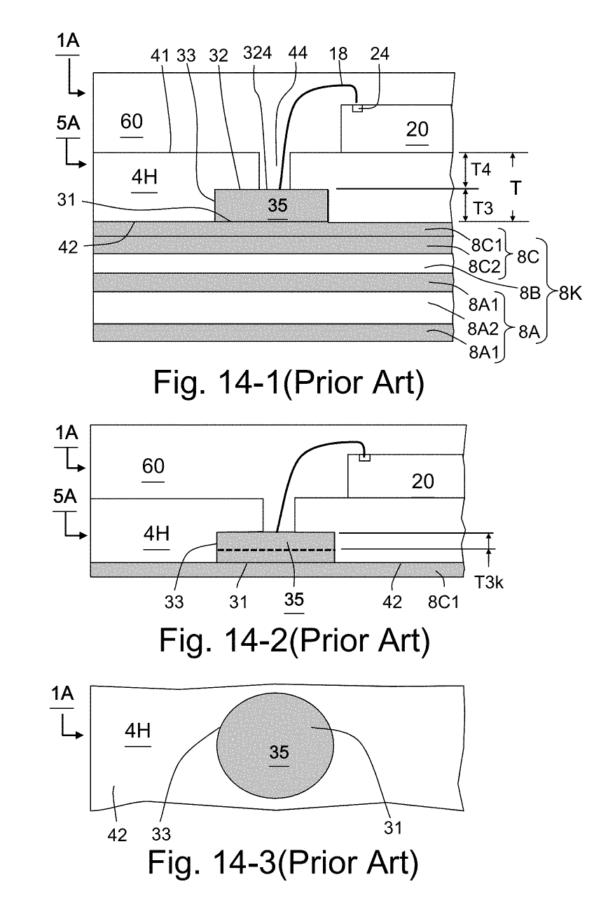

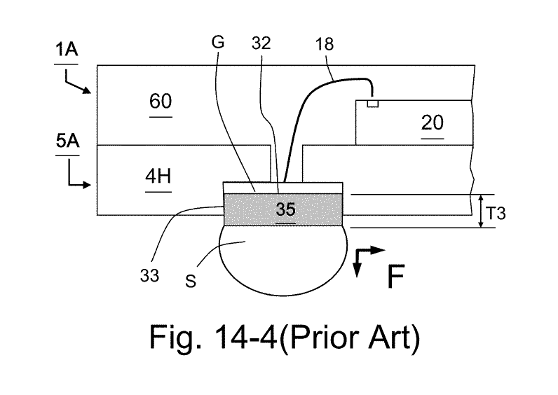

Referring to FIGS. 1-1 to 1-2, FIG. 1-1 shows a structure of a printed circuit board 51 and a carrier 80 (i.e. a structure comprised of a printed circuit board 51 and a carrier 80), wherein the printed circuit board 51 includes a trace 30 and a dielectric layer 90; the carrier 80 is coupled with the dielectric layer 90 of the printed circuit board 51, then both the printed circuit board 51 and the carrier 80 are stack, and a thickness T5 of a printed circuit board 51 is not less than 30 μm (i.e., T5≤30 μm), such as 25 μm, 20 μm, 10 μm, 2 μm etc., so as to thin the printed circuit board 51, wherein the trace 30 is configured to transmit electricity and made of copper or nickel and/or the like, the trace 30 has an upper surface 31, a lower surface 32, a side edge 33, and a thickness T30, wherein the thickness T30 is equal to or is less than 10 μm (i.e., T30≤10 μm), such as 10 μm, 5 μm, 3 μm, 1 μm etc., so as to thin the printed circuit board 51. The trace 30 at least has a terminal 3A, meanwhile, the trace 30 also enables to have an extending portion 3B adjacent to the terminal 3A. In this embodiment, the trace 30 has both the terminal 3A and the extending portion 3B adjacent to the terminal 3A, wherein the upper surface 31 of the trace 30 consists of both the upper surface 3A1 of the terminal 3A and the upper surface 3B1 of the extending portion 3B, the lower surface 32 of the trace 30 consists of both the lower surface of the terminal 3A and the lower surface of the extending portion 3B, and the terminal 3A is configured to transmit the electricity, wherein the periphery of the upper surface 3A1 of the terminal 3A is employed as an attached area 3A4, and the upper surface 31 and the lower surface 32 of the trace 30 are in any one of a rectangle shape, a circle shape, a polygon shape, and other shapes so that the extending portion 3B of the trace 30 extends freely on the lower surface 42 of the dielectric layer 90 made of insulating material, such as solder mask or epoxy or the like, wherein the dielectric layer 90 has a predetermined opening 9F, an upper surface 91, a lower surface 92, and a side edge 93, wherein the predetermined opening 9F is formed by a portion 90F of the dielectric layer 90 which is corresponding to the terminal 3A of the trace 30, in this manner, the predetermined opening 9F of the dielectric layer 90 is not penetrated through the dielectric layer 90, the lower surface 92 of the dielectric layer 90 is coupled with the upper surface 31 of the trace 30 so that the upper surface 31 of the trace 30 is sealed and does not expose outside the dielectric layer 90 completely. Thereby, the dielectric layer 90 protects the trace 30 in a packaging process to avoid the trace 30 being etched by etching solution, so that a portion of the trace 30 (as shown in FIG. 14-2) is not eliminated, then it can prevent the trace 30 from being damaged by the gap G (as shown in FIG. 14-4) so as to thin the thickness T30 of the trace 30. When the thickness T30 of the trace 30 is thinned, the thickness T5 of the circuited circuit board 51 is thinned too, thus enhancing usage of the printed circuit board 51 in electronics industry. The portion 90F of the dielectric layer 90 is eliminated in the packaging process so that the predetermined opening 9F is transferred to be an opening which is penetrated through the dielectric layer 90, as shown in FIG. 9-4, and the terminal 3A of the trace 30 conducts the electricity. Referring to FIG. 1-1, the printed circuit board 51 includes the trace 30 and the dielectric layer 90 which are stacked exclusively, hence the thickness T5 of the printed circuit board 51 is not less than 30 μm or 2 μm, thus thinning the printed circuit board 51. A carrier 80 is made of metal, such as copper, alloy, etc. Alternatively, the carrier 80 is made of non-metal, such as resin or the like. The carrier 80 includes an upper surface 81, a lower surface 82, and a side edge 83, wherein the carrier 80 is coupled with the dielectric layer 90. As shown in FIG. 1-1, the lower surface 82 of the carrier 80 is connected with the upper surface 91 of the dielectric layer 90 so that the upper surface 81 of the carrier 80 exposes to the atmosphere. The carrier 80 enables to be replaced by a carrier 80, 88, or 8K as illustrated in FIGS. 2 to 14-1 respectively; the carrier 80 is comprised of at least an element and/or a plurality of elements. Referring to FIG. 1-1, the carrier 80 is comprised of an element which is made of metal, and the carrier 80 is maintained (as shown in FIG. 13-4) or is eliminated (as shown in FIG. 10-4) eventually. The carrier 80 is maintained as shown in FIG. 1-1, such that the printed circuit board 51 further enables to include a film 65 (denoted by a dotted line) configured to avoid electromagnetic interference. The side edge 83 of the carrier 80 is exposed out of the side edge 93 of the dielectric layer 90, then The film 65 is connected with the side edge 83 of the carrier 80 and the side edge of the dielectric layer 90, and another film 65 can be arranged on a surface 6S of a encapsulant 60 and a side edge 53 of the printed circuit board 51, after the printed circuit board 51 and a chip are connected to produce a semiconductor package 10 (as shown in FIG. 13-4). The film 65 of the printed circuit board 51 is connected with another film 65 of the semiconductor package 10, thus it allows that the carrier 80 is for electromagnetic shielding, then increasing an area of the electromagnetic shielding of the semiconductor package 10 by using the carrier 80, and enhancing resistance of the semiconductor package 10 against the electromagnetic interference. Moreover, the carrier 80 also enables to have an opening (refer to FIG. 8, numeral 86) which is penetrated through or not penetrated the carrier 80, and the opening can be corresponding and/or not corresponding to the predetermined opening 9A, the opening of carrier 80 can be used for enhancing the condition of the thermal expansion of the carrier 80 so as to adjust the warpage of the printed circuit board 51, then the warpage of the carrier 80 can be complied with the specification of the warpage of the semiconductor package, and then it can prevent the printed circuit board 51 from being damaged caused by out of the rang of the warpage, wherein the shape of the opening of the carrier 80 can be a circle, a square, a rectangle, and/or the like. With reference to FIG. 9-3, the carrier 80 is eliminated by way of the etching solution, due to the dielectric layer 90 seals the upper surface 31 of the trace 30 fully so that the trace 30 is not etched by the etching solution, thus enhancing a quality of the printed circuit board 51 and decreasing the thickness and the fabrication cost of the printed circuit board 51 and the semiconductor package 10. Referring to FIG. 1-1, the dielectric layer 90 is coupled with the lower surface 82 of the carrier 80 and is defined between the trace 30 and the carrier 80, wherein the dielectric layer 90 has the predetermined opening 9F comprised of the portion 90F of the dielectric layer 90 so that the predetermined opening 9F does not pass through the dielectric layer 90, thus enhancing the rigidity of the printed circuit board 51 and the carrier 80 to avoid bending and/or breaking the printed circuit board 51 and the carrier 80. As shown in FIG. 3, the printed circuit board 51 further includes an insulator 40 so that the dielectric layer 90 is defined among the carrier 80, the trace 30, and the insulator 40, thus more enhancing the rigidity of the printed circuit board 51 and the carrier 80 and avoiding the bending and/or breaking the structure of the printed circuit board 51 and the carrier 80. As shown in FIG. 3, the insulator 40 includes a via 44, such that the printed circuit board 51 enables to include a second trace 70, as illustrated in FIG. 7, so as to increase the density of the printed circuit board 51.

With reference to FIG. 2, in another embodiment, the thickness T5 of the printed circuit board 50 is equal to the thickness T30 of the trace 30 (as shown in FIG. 1-1), and the side edge 33 of the trace 30 is also coupled with the dielectric layer 90 to increase a connection area of the trace 30 and the dielectric layer 90, thus the trace can be held by the dielectric layer 90 more securely so as to avoid the trace 30 peeling off from the dielectric layer 90.

With reference to FIG. 3, in another embodiment, the thickness T40 of the insulator 40 is less than or is equal to 30 μm (i.e., T40≤30 am), such as 25 μm, 20 μm, 10 μm, 2 μm etc., so as to thin the printed circuit board 50, wherein the printed circuit board 50 further includes the insulator 40 which has an upper surface 41, a lower surface 42, a side edge 43, and a via 44 which penetrates the insulator 40, wherein the insulator 40 is made of insulating material, such as epoxy or solder mask or the like, etc. The thickness T40 of the insulator 40 is comprised of the thickness T4 between the lower surface 32 of the trace 30 and the upper surface 41 of the insulator 40 and the thickness T30 of the trace 30, wherein the insulator 40 is coupled with the lower surface 92 of the dielectric layer 90, and the insulator 40 is also coupled with both the lower surface 32 and the side edge 33 of the trace 30. Since the structure of the printed circuit board 50 and the carrier 88 further includes the insulator 40, in this manner, it allows that the lower surface 92 of the dielectric layer 90 is coupled with both the trace 30 and the insulator 40 so as to increase a connection area of the lower surface 92 of the dielectric layer 90. The upper surface 91 of the dielectric layer 90 is coupled with the carrier 88 so that the dielectric layer 99 is defined among the carrier 88, the trace 30, and the insulator 40, such that the lower surface 92 of the dielectric layer 90 is sealed by both the trace 30 and the insulator 40 fully (i.e., the dielectric layer 90 is like a sandwich to be defined among the carrier 88, the trace 30, and the insulator 40), thus more enhancing the rigidity of the printed circuit board 50 and the carrier 80 to avoid bending and/or breaking of the structure of the printed circuit board 50 and the carrier 88. Preferably, the printed circuit board 50 is fixed by the carrier 88, the trace 30, and the insulator 40 more securely to enhance the rigidity of the printed circuit board 50 and the carrier 88 and to avoid bending and/or breaking the printed circuit board 50 and the carrier 88. Due to The insulator 40 seals the lower surface 32 and the side edge 33 of the trace 30 to prevent the trace 30 from being damaged caused by an impact and to enhance the rigidity of the printed circuit board 50 and the carrier 88. Furthermore, the via 44 of the insulator 40 corresponds to the lower surface 32 of the trace 30, and the portion of the lower surface 32 of the trace 30 exposing to the via 44 of the insulator 40 is employed as a contact 324, and the contact 324 of the trace 30 is for externally electrical connection. Still referring to FIG. 3, the contact 324 exposes to the via 44 of the insulator 40, when the printed circuit board 50 includes a second trace 70 (as shown in FIG. 4), the printed circuit board 50 has a high density so as to arrange more traces on the printed circuit board 50, wherein the carrier 88 is comprised of an adjustment layer 801 and another 80 which is connected with the adjustment layer 801, the lower surface of another carrier 80 is employed as the lower surface 82 of the carrier 88, the lower surface of another carrier 80 is coupled with the upper surface 91 of the dielectric layer 90 of the printed circuit board 50, and the surface of the adjustment layer 801 exposing to the atmosphere is employed as the upper surface 81 of the carrier 88, wherein the adjustment layer 801 is made of any one of insulating material, prepreg, and solder mask. The rigidity of the printed circuit board 50 is enhanced and the cost of the printed circuit board 50 is reduced by using the adjustment layer 801. When the carrier 80 is made of copper, the thickness of the carrier 80 is more than 36 μm, thus increasing material cost. In addition, when manufacturing the printed circuit board 50, the working panel is cut into multiple substrates of the printed circuit board 50 by using a milling cutter, thus having quick damage and high fabrication cost. Because the Coefficient of Thermal Expansion (CTE) of the copper is high, the multiple substrates of the printed circuit boards 50 warp greatly and are collided seriously. To overcome this problem, the thickness of the carrier 80 is reduced to within 3 μm to 18 μm by way of the adjustment layer 801 of the another carrier 80, thus decreasing the fabrication cost and maintaining the rigidity of the printed circuit board 50. The carrier 88 is comprised of the adjustment layer 801 and the another carrier 80, so the carrier 88 enables not to include a detachable cooper foil 8C of the carrier 8K and the prepreg 8B (as shown in FIG. 14-1), thus lowering material cost and the fabrication cost.

With reference to FIG. 14-1, in case that the printed circuit board 50 is connected with the carrier 8k shown in FIG. 14-1 ALSO CAN to avoid defects that the conventional printed circuit board 5A have, explanations following:

(1). In the packaging process, when a coupling layer 8C1 of the carrier 8K is eliminated by using the etching solution (as illustrated in FIGS. 9-1 to 9-3), the trace 30 is not etched by the etching solution because the upper surface 31 of the trace 30 is sealed by the dielectric layer 90 fully. Accordingly, the thickness T30 of the trace 30 is less than the thickness T3 of the conventional trace 35, wherein the thickness T30 of the trace 30 is 11 μm, 7 μm, 4 μm or 1 μm so as to thin the printed circuit board 50 and the semiconductor package and to reduce the material cost.

(2) When the trace 30 and a solder ball S (as shown in FIG. 9-4) are connected, the attached area 3A4 of the trace 30 is sealed by the dielectric layer 90 (as shown in FIG. 9-4), and the trace 30 is connected with the insulator 40 firmly, such that when the solder ball S is impacted by an external force F, the lower surface 32 of the trace 30 is not separated from the insulator 40. After the carrier 88 of FIG. 3 is replaced by the carrier 8K of FIG. 14-1, the coupling layer 8C1 of the carrier 8K can be selectively served as the carrier 80, as illustrated in FIG. 1-1.

Referring to FIG. 3A, in another embodiment, the insulator 40 does not include the via 44 of FIG. 3, and a portion of the lower surface 32 of the trace 30 exposing outside the insulator 40 is the contact 324 configured to transmit the electricity, wherein the contact 324 is close to the chip 20 (denoted by the dotted line) so that a distance D1 between the chip 20 and the contact 324 of the trace 30 reduces, and a distance between the terminal 24 of the chip 20 and the contact 324 of the trace 30 decreases, thus reducing a length and a cost of a wire 18 (represented by a dotted line). The wire 18 is made of any one of gold, silver, copper and other conductive materials so as to electrically conduct the chip 20 with the printed circuit board 51. Furthermore, the contact 324 has a conductive layer (not shown) so as to transmit the electricity. The carrier 80 is made of metal so as to obtain the electromagnetic shielding of the carrier 80. The printed circuit board 51 further includes a film 65 (denoted by a dotted line) configured to obtain the electromagnetic shielding, wherein the film 65 is connected with the side edge 83 of the carrier 80, the side edge 93 of the dielectric layer 90, and the side edge 43 of the insulator 40. Due to the film 65 is connected with the side edge 43 of the insulator 40, a connection area of the film 65 and the printed circuit board 51 is increased to avoid the film 65 peeling off from the printed circuit board 51. In addition, the carrier 80 has an opening 86 (as shown in FIG. 13-4) corresponding to the terminal 3A of the trace 30.

As shown in FIG. 4, in another embodiment, a printed circuit board 51 comprises a second trace 70 configured to transmit the electricity, and the second trace 70 includes an upper surface 71, a lower surface 72, a side edge 73, and a protruded portion 79 which is formed on the lower surface 72 of the second trace 70, and the lower surface 72 of the second trace 70 is coupled with the upper surface 41 of the insulator 40, wherein the protruded portion 79 is accommodated in the via 44 of the insulator 40 and is electrically connected with the contact 324 of the trace 30 so as to enhance a trace density of the printed circuit board 51 in a fixed area of the printed circuit board 51. Preferably, the second trace 70 extends freely on the upper surface 41 of the insulator 40 to enhance utility of the printed circuit board 51 and the carrier 80.

Furthermore, the carrier 88 includes a blind via 87 formed on the adjustment layer 801, and the blind via 87 has a width L and a depth D, wherein the depth D is changeable to determine whether the blind via 87 passes through or does not pass through the adjustment layer 801. In this embodiment, the blind via 87 passes through the adjustment layer 801 so that a portion of the carrier 80 exposes to the blind via 87 and does not pass through the carrier 88. Preferably, the coefficient of thermal expansion (CTE) of the carrier 88 is changeable by changing the width L and/or the depth D of the blind via 87 so as to improve the warpage of the printed circuit board 51 and to avoid the damage of the printed circuit board 51. Meanwhile, the etching solution flows to the another carrier 80 from the blind via 87 via the adjustment layer 801 and the another carrier 80 (as shown in FIG. 10-3) so as to eliminate the another carrier 80, thus simplifying the carrier 88 of the printed circuit board 51 to save the fabrication cost and/or to enhance the production efficiency. The insulator 40 further enables to include a solder mask (not shown) situated on the upper surface 41 thereof to protect the second trace 70, and the second trace 70 further has a conductive layer (not shown) formed on the upper surface 71 thereof so as to transmit the electricity.

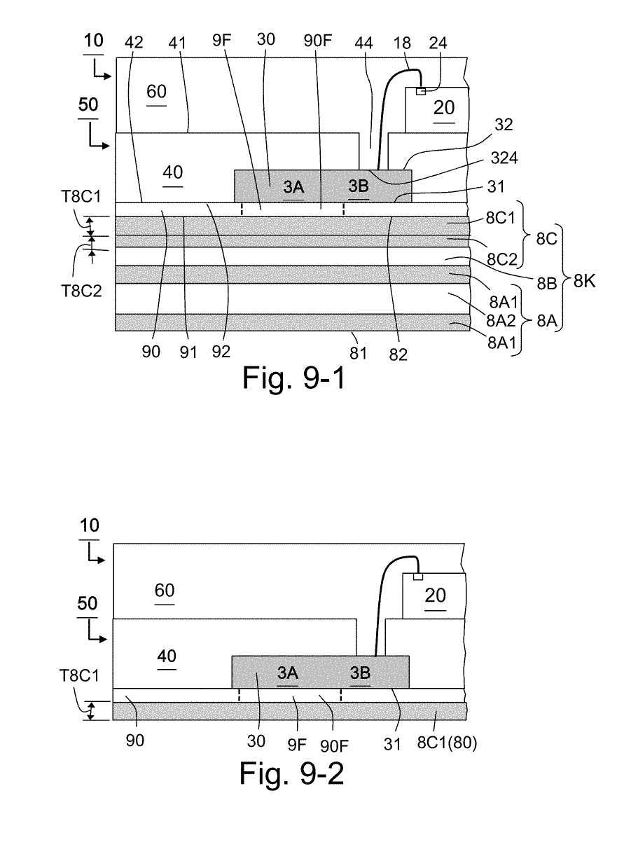

As illustrated in FIG. 5, in another embodiment, the structure of the printed circuit board 51 and the carrier 80 shown in FIG. 5 is similar to the structure of the printed circuit board 50 and the carrier 80 shown in FIG. 2, wherein the structure of the printed circuit board 51 and the carrier 80 further includes an insulator 40, and the insulator 40 includes an upper surface 41, a lower surface 42, a side edge 43, and a via 44, the insulator 40 is coupled with both the lower surface 92 of the dielectric layer 90 and the lower surface 32 of the trace 30, wherein the via 44 corresponds to the lower surface 32 of the trace 30, in this manner, a portion of the lower surface 32 of the trace 30 exposing to the via 44 of the insulator 40 is employed as the contact 324 configured to transmit the electricity. Moreover, the printed circuit board 51 further includes a second trace 70 (indicated by a dotted line) which is for externally electrical connection, and the second trace 70 includes an upper surface 71, a lower surface 72, a side edge 73, and a protruded portion 79, wherein the protruded portion 79 is formed on the lower surface 72, and the lower surface 72 is coupled with the upper surface 41 of the insulator 40 so that the protruded portion 79 is accommodated in the via 44 of the insulator 40 and is electricity connected with the contact 324 of the trace 30, hence the density of the printed circuit board 51 is increased.

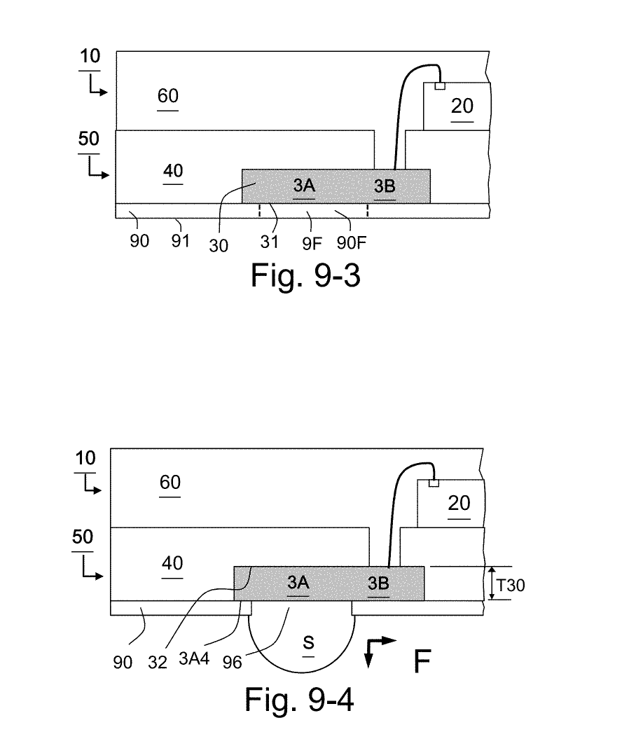

With reference to FIG. 6, in another embodiment, the structure of the printed circuit board 51 and the carrier 80 shown in FIG. 6 is similar to the structure of the printed circuit board 50 and the carrier 80 shown in FIG. 2, wherein the trace 30 of the printed circuit board 51 further comprises a protruded portion 39, wherein the protruded portion 39 is formed on the lower surface 32 of the trace 30. Meanwhile, the printed circuit board 51 further comprises a second trace 70 and an insulator 40, wherein the second trace 70 has a side edge 73, an upper surface 71, and a lower surface 72, wherein a portion of the lower surface 72 is employed as a contact 724 which is for externally electrical connection, and the insulator 40 includes an upper surface 41, a lower surface 42, and a via 44. The lower surface 42 of insulator 40 is coupled with both the lower surface 92 of the dielectric layer 90 and the lower surface 32 of the trace 30, wherein the second trace 70 is situated on the upper surface 41 of the insulator 40, and the insulator 40 seals both the lower surface 72 and the side edge 73 of the second trace 70, wherein the upper surface 71 of the second trace 70 exposes to the upper surface 41 of the insulator 40, and the contact 724 of the second trace 70 exposes to the via 44, wherein the via 44 of the insulator 40 corresponds to the protruded portion 39, and the protruded portion 39 of the trace 30 is accommodated in the via 44, in this manner, the trace 30 enables to be electrically connected with the contact 724 of the second trace 70. Wherein because the trace 30 has the protruded portion 39, then Not only the trace 30 enables to be coupled with the dielectric layer 90 but the protruded portion 39 of the trace 30 also enables to be coupled with the insulator 40 so as to fix the trace 30 in the printed circuit board 51 more securely, thus avoiding the trance 30 peeling off from the dielectric layer 90 and/or the insulator 40. Due to the trace 30 is made of metal, and the dielectric layer 90 and the insulator 40 are made of the insulating material, wherein the CTE of the metal is larger than the insulating material. When the printed circuit board 51 is heated, for example: 100° C., it produces a stress so that the trace 30 pulls both the dielectric layer 90 and the insulator 40, and when the printed circuit board 51 is cooled, for example: 0° C., the trace 30 pulls the dielectric layer 90 and the insulator 40 repeatedly, thus it is easy to cause the trace 30 peeled off the dielectric layer 90 and/or the insulator 40. due to the trace 30 is fixed by both the dielectric layer 90 and the insulator 40 more securely, it will not be peeled off, and due to the printed circuit board 51 has the second trace 70 so as to increase a high density of trace to achieve more utility.

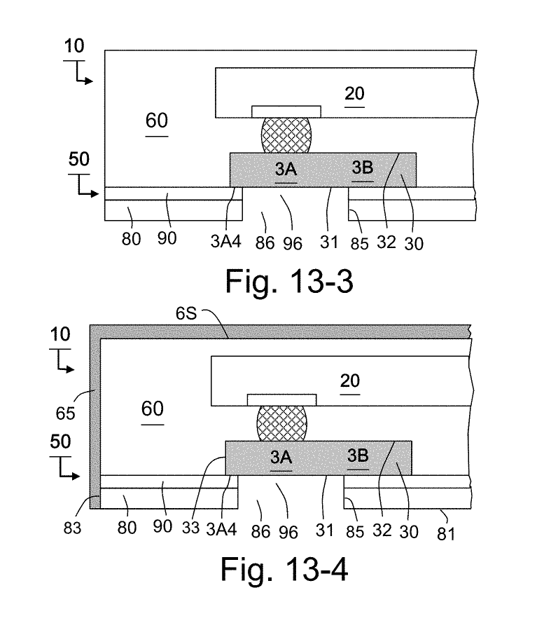

With reference to FIG. 7, in another embodiment, wherein the carrier 80 further has an opening 86 which passes through the carrier 80, and wherein the opening 86 of the carrier 80 has a side wall 85, and the opening 86 corresponds to the terminal 3A of the trace 30. The printed circuit board 51 of this embodiment is identical to the printed circuit board 50 of FIG. 3. However, in this embodiment, the dielectric layer 90 further includes a protruded portion 99 wherein the protruded portion 99 is formed on the upper surface 91 of the dielectric layer 90, said protruded portion 99 of the dielectric layer 90 is between the predetermined opening 9F of the dielectric layer 90 and the side wall 85 of the opening 86 of the carrier 80, said protruded portion 99 of the dielectric layer 90 is accommodated in the opening 86 of the carrier 80, in this manner, said protruded portion 99 of the dielectric layer 90 is coupled with the side wall 85 of the opening 86 of the carrier 80, meanwhile the portion 90F of the dielectric layer 90 is accommodated in the opening 86 of the carrier 80 (i.e. the predetermined opening 9F of the dielectric layer 90 is received in the opening 86 of the carrier 80) too, wherein due to both the side wall 85 of the opening 86 and the lower surface 82 of the carrier 80 are coupled with the dielectric layer 90 simotaniosly, thus the contacted areas that the carrier 80 coupled with the dielectric layer 90 enables to be increased, then the peeling-off problem can be avoided. In the packaging process, the carrier 80 is either eliminated (as shown in FIG. 10-4) or is maintained (as shown in FIG. 7 or FIG. 12-2) eventually, so that the carrier 80 is applied flexibly. As shown in FIG. 7, the carrier 80 is maintained eventually so as to enhance the rigidity of the structure of the printed circuit board 51 and the carrier 80 and to avoid bending and/or breaking of the structure of the printed circuit board 51 and the carrier 80. In addition, the carrier 80 enables to be made of metal(s) such as a copper, nickel, alloy, and/or the like so as to enhance heat dissipation of the semiconductor package. Alternatively, the carrier 80 includes a metal layer or a film (as shown in FIG. 12-3) so as to increase an area of the semiconductor package to resist against electromagnetic interference, thus increasing utility of the structure of the printed circuit board 51 and the carrier 80. Preferably, the upper surface 81 of the carrier 80 enables to be coupled with a second dielectric layer 95 so as to protect the carrier 80, wherein the second dielectric layer 95 is coupled with both the upper surface 81 of the carrier 80 and the dielectric layer 90, moreover, the second dielectric layer 95 further enables to be coupled with another carrier, such as the carrier 8K of FIG. 14-1, wherein when the second dielectric layer 95 is coupled with another carrier 8K of FIG. 14-1, another carrier 8k is coupled with the second dielectric layer 95 by using the coupling layer 8C1. In addition, the another carrier 8k enables to be also applied to avoid the bending of the printed circuit board 51, the another carrier 8k can be exchanged with the carrier 88 as illustrated in FIGS. 3-4. Thereby, the insulator 40 of printed circuit board 51 can be omitted so that the upper surface 32 and the side edge 33 of the trace 30 expose outside the dielectric layer 90, thus thinning the printed circuit board 51. When the printed circuit board 51 does not include the insulator 40, the dielectric layer 90 also enables to be coupled with the side edge 33 (as shown in FIG. 2) of the trace 30 so as to enhance a connection area of the trace 30 and the dielectric layer 90, thus avoiding the trace 30 peeling off from the dielectric layer 90. Preferably, the trace 30 further includes a protruded portion 39 (as shown in FIG. 6) or an insulator 40 formed on the lower surface 32 (as illustrated in FIG. 5). in addition, the side edge 83 of carrier 80 also enables to be coupled with the dielectric layer 90 so as to avoid the peeling-off problem.

With reference to FIG. 8, in another embodiment, the structure of the printed circuit board 50 and the carrier 80 shown in FIG. 8 is similar to the structure of the printed circuit board 51 and the carrier 80 shown in FIG. 7, wherein the predetermined opening 9F of the dielectric layer 90 of the printed circuit board 51 shown in FIG. 7 is transferred to be the opening 96 of the dielectric layer 90 of the printed circuit board 50 shown in FIG. 8, the opening 96 of dielectric layer 90 penetrates the dielectric layer 90, and the opening 96 of dielectric layer 90 corresponds to the terminal 3A of the trace 30 and the opening 86 of the carrier 80, the terminal 3A of the trace 30 exposes to the opening 96 of the dielectric layer 90 for externally electrical connection, wherein the protruded portion 99 is formed on the upper surface 91 of the dielectric layer 90, said protruded portion 99 of the dielectric layer 90 is between the opening 96 of the dielectric layer 90 and the side wall 85 of the opening 86 of the carrier 80, said protruded portion 99 of the dielectric layer 90 is accommodated in the opening 86 of the carrier 80, in this manner, said protruded portion 99 of the dielectric layer 90 is coupled with the side wall 85 of the opening 86 of the carrier 80, due to the protruded portion 99 of the dielectric layer 90 is accommodated in the opening 86 of the carrier 80 so that the protruded portion 99 of the dielectric layer 90 is coupled with the side wall 85 of the opening 86 of the carrier, hence the dielectric layer 90 is coupled with both the lower surface 82 and the side wall 85 of the carrier 80 to enhance a connection area and strength of the carrier 80 and the dielectric layer 90, thus avoiding the carrier 80 peeling off from the dielectric layer 90. Meanwhile, the protruded portion 99 of the dielectric layer 90 enables to be used for preventing the printed circuit board 50 from being damaged by a short-circuited problem, due to said protruded portion 99 of the dielectric layer 90 can be served as a dam which is able to stop the solder ball S shown in FIG. 12-3 touching the upper surface 81 of the carrier 80, Moreover, a height of the protruded portion 99 of the dielectric layer 90 enables to be either more than or is equal to the upper surface 81 of the carrier 80. Alternatively, at least one portion of the protruded portion 99 of the dielectric layer 90 is not coupled with the side wall 85 of the opening 86 of the carrier 80, such that a portion of the side wall 85 of the opening 86 of the carrier 80 exposes to the protruded portion 99 of the dielectric layer 90 so that the carrier 80 electrically enables to be connected with the trace 30 by using the side wall 85 by tin or other conductive elements as required. In addition, the carrier 80 further enables to include a second dielectric layer 95 coupled with the upper surface 81 so as to protect the carrier 80, wherein the second dielectric layer 95 includes an opening corresponding to the opening 86 of the carrier 80, the opening 96 of the dielectric layer 90, and the terminal 3A of the trace 30. As shown in FIGS. 1-1 to 8, each of the printed circuit boards 50, 51 has the features that the upper surface 31 of the trace 30 sealed by the dielectric layer 90, and the traces 30, 70 and/or the carriers 80, 88 are arranged on each printed circuit board 50 or 51 based on using requirements. As illustrated in FIG. 8, the insulator 40 of the printed circuit board 50 enables to be omitted as required, so that the lower surface 32 and the side edge 33 of the trace 30 expose outside the dielectric layer 90 so as to thin the thickness of the printed circuit board 50. When the printed circuit board 50 does not include the insulator 40, the side edge 33 of the trace 30 (as shown in FIG. 2) also enables to be coupled with the dielectric layer 90 so as to increase a connection area of the trace 30 and the dielectric layer 90, thus avoiding the trace 30 peeling off from the dielectric layer 90. Preferably, the trace 30 further enables to include a protruded portion 39 (as shown in FIG. 6) or an insulator 40 (as shown in FIG. 5) formed on the lower 32 of the trace 30 based on using requirements.

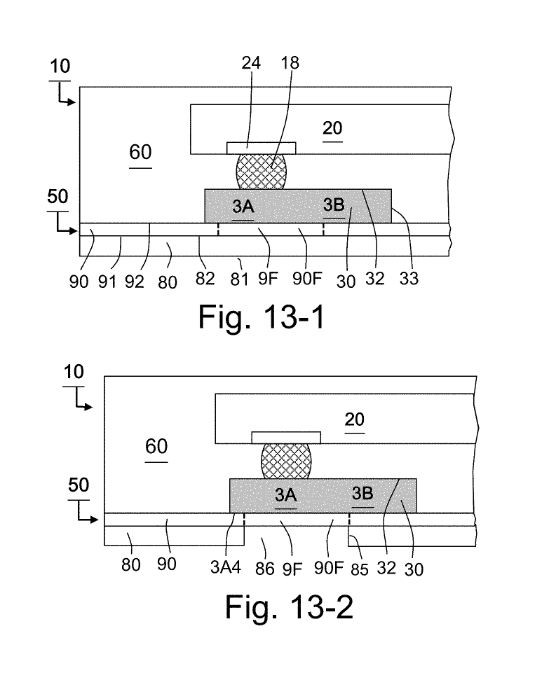

Referring to FIG. 9-1, in a manufacturing method of the semiconductor package 10, a structure of the printed circuit board 50 and a carrier 8K is provided, wherein the printed circuit board 50 is the same as the printed circuit board 50 shown in FIG. 3, and the carrier 8K is the same as the carrier 8K shown in FIG. 14-1. The coupling layer 8C1 of the carrier 8K is connected with the upper surface 91 of the dielectric layer 90, and the bottom of the coupling layer 8C1 is employed as the lower surface 82 of the carrier 8K, wherein the top of the copper clad laminate 8A is employed as the upper surface 81 of the carrier 8K, and the chip 20 is coupled with the printed circuit board 50. In addition, the chip 20 (as shown in FIG. 9-1) is arranged on the upper surface 41 of the insulator 40, two ends of a conductive element 18 (i.e., the wire) are connected with the terminal 24 of the chip 20 and the contact 324 of the trace 30 of the printed circuit board 50 respectively so that the chip 20 is electrically connected with the printed circuit board 50. Thereafter, the chip 20, the conductive element 18, and the printed circuit board 50 are packaged by an encapsulant 60, thus producing the semiconductor package. The chip 20 can be employed as a flip chip and the conductive element 18 can be employed as a bump shown in FIG. 11-1, wherein the coupling layer 8C1 of the carrier 8K (as shown in FIG. 9-1) can be employed as the carrier 80 as illustrated in FIG. 1-1, such that the structure of the printed circuit board and the carrier is produced based on the using requirements. With reference to FIGS. 9-2 to 9-3 showing a removal process is provided, this removed process is for removing the carrier 8k away from the printed circuit board 50, i.e., the carrier 8k is eliminated. For example, as shown in FIG. 9-2, the coupling layer 8C1 of the detachable copper foil 8C is removed from the detachable layer 8C2 so as to eliminate the detachable layer 8C2, the prepreg 8B and the copper clad laminate 8A, and the coupling layer 8C1 (80) of the carrier 8K is coupled with the dielectric layer 90 only. As illustrated in FIG. 9-2, then the coupling layer 8C1 (80) enables to be employed as the carrier 80 as required, wherein the detachable layer 8C2, the prepreg 8B, and the copper clad laminate 8A are eliminated manually or automatically by using machine(s).

Referring to FIG. 9-3, the coupling layer 8C1 is removed so as to eliminate the carrier 8K completely, and the upper surface 91 of the dielectric layer 90 exposes to the atmosphere. As shown in FIG. 9-3, the coupling layer 8C1 is eliminated by etching solution, wherein the trace 30 is not etched because the trace 30 is sealed by the dielectric layer 90 completely. With reference to FIG. 9-4 showing a drilling process is provided this drilling process is for the predetermined opening 9F being transferred to be an opening, the opening is formed in a laser manner or by way of chemical solvent. For example, the portion 90F of the dielectric layer 90 is removed so that the predetermined opening 9F is transferred to be an opening which passes though the dielectric layer 90, and the terminal 3A of the trace 30 enables to be for externally electrical connection. In this embodiment, the terminal 3A electrically connects to the solder ball S, wherein an attached area 3A4 of the side edge of the terminal 3A is coupled with the dielectric layer 90 so that the trace 30 is connected with the insulator 40 securely. When the solder ball S is impacted by an external force, the lower surface 32 of the trace 30 is not removed from the insulator 40, i.e., no gap occurs between the trace 30 and the insulator 40, as shown in FIG. 14-1. Thereby, the thickness T3 of the trace 30 is thinner than the thickness T3 of the trace 35, thus thinning the printed circuit board. The trace 30 further enables to include the conductive layer (not shown) so as to transmit the electricity. Referring to FIG. 9-1, the coupling layer 8C1 has a thickness T8C1 which is around 18 μm (or other thickness), wherein the detachable layer 8C2 has a thickness T8C2 which is approximately 3 μm to 5 μm, and the thickness T8C1 of the coupling layer 8C1 is more than the thickness T8C2 of the detachable layer 8C2 (i.e., T8C1>T8C2), thus avoiding a damage of the printed circuit board. In an eliminating process, as shown in FIGS. 9-2 and 9-3, the thickness T8C1 of the coupling layer 8C1 is thicker than the thickness T8C2 of the detachable layer 8C2 so that the coupling layer 8C1 is connected with the dielectric layer 90 fixedly. When the coupling layer 8C1 of the detachable copper foil 8C is detached from the detachable layer 8C2, the coupling 8C1 is not pulled by the detachable layer 8C2 to be broken, and the dielectric layer 90 (or even the printed circuit board 50) is not broken either. When the coupling layer 8C1 is not broken by the detachable layer 8C2, the thickness T8C1 of the coupling layer 8C1 enables to be less than the thickness T8C2 of the detachable layer 8C2 (i.e., T8C1<T8C2) as required, during the period of manufacturing the semiconductor package 10. By means of the detachable layer 8C2 of the detachable copper foil 8C, the coupling layer 8C1 of the detachable copper foil 8C enables to be removed from the dielectric layer 90 rapidly, thus the efficiency of production enables to be enhanced. In addition, the drilling process is provided, after the encapsulant 60 seals the chip 20 and the printed circuit board 50, i.e., the portion 90F is removed, after the encapsulant 60 seals the chip 20 and the printed circuit board 50, and the external material such as the solder balls are coupled with the terminal 3A within a period of time, such as 8 hours so as to prevent the terminal 3A from being rusted caused by oxidation and/or moisture in the atmosphere.

As shown in FIGS. 10-1 to 10-5, in a manufacturing method of the semiconductor package 10 of a structure of the printed circuit board 51 and the carrier 88, the printed circuit board 51 is the same as the printed circuit board 50 shown in FIG. 4, and the carrier 88 is identical to that of FIG. 3. As illustrated in FIGS. 3-4, the carrier 88 further includes one or more elements arranged on the upper layer 81 thereof according to using requirements, for example, a copper layer, an insulation layer and/or other elements are arranged on the upper layer 81 of the carrier 80, and the chip 20 is provided on the upper surface 41 of the insulator 40 so that the chip 20 is connected with the printed circuit board 51. Thereafter, a conductive element 18 is a wire and its two ends are connected with the terminal 24 of the chip 20 and the second trace 70 of the printed circuit board 51 respectively so that the chip 20 is electrically connected with the printed circuit board 51, and the encapsulant 60 encapsulates the chip 20, the conductive element 18, and the printed circuit board 51, thus finishing the semiconductor package 10. Referring further to FIGS. 10-2 to 10-4 showing a removal process is provided which is for removing the carrier 88 away from the printed circuit board 51, the carrier 88 is eliminated, wherein the adjustment layer 801 has a blind via 87 passing through the adjustment layer 801, as illustrated in FIG. 10-2, and a portion of another carrier 80 exposes to the blind via 87. The blind via 87 is configured to adjust a buckling of the printed circuit board 51, and the etching solution flows through the adjustment layer 801 to remove another carrier 80, as shown in FIG. 10-3. With reference to FIG. 10-2, the blind via 87 corresponds to the predetermined opening 9F. Alternatively, the blind via 87 enables to correspond to and/or not to correspond to the predetermined opening 9F and is formed in any one of a circle shape, a rectangle shape, a strip shape and/or other shapes. The blind via 87 is formed in a laser manner or by way of chemical solvent. Referring to FIG. 10-3 showing providing an etching solution M, the etching solution M flows through the blind via 87 to contact with another carrier 80, thus eliminating another carrier 80 and the carrier 88 eliminated too (as ill-starred in FIG. 10-4). The blind via 87 is configured to accommodate the etching solution M and the etching solution M flows through the adjustment layer 801 to remove the carrier 80, thus simplifying the structure of the printed circuit board 51 and the carrier 88 so as to avoid a complicated carrier 8K of FIG. 14-1, to save manufacture cost and/or to enhance production efficiency, As shown in FIG. 10-4, the upper surface 91 of the dielectric layer 90 of the printed circuit board 51 exposes to the atmosphere, after removing the carrier 88. The trace 30 is encapsulated by the dielectric layer 90 so as not to be etched by the etching solution. As illustrated in FIG. 10-5 showing a drilling process is provided, this drilling process is for the portion 90F of the dielectric layer 90 is removed so that the predetermined opening 9F is transferred to be the opening 96, and the terminal 3A of the trace 30 is for externally electrical transferred to be an opening 96 which penetrates the dielectric layer 90, wherein the attached area 3A4 of the terminal 3A is coupled with the dielectric layer 90 so that the trace 30 is connected with the insulator 40 securely, and no any gap occurs between the lower surface 32 of the trace 30 and the insulator 40, as shown in FIG. 14-4. Preferably, the opening 96 is formed in a laser manner or by way of chemical solvent. Moreover, a solder ball S (denoted by a dotted line) is electrically connected with the terminal 3A of the trace 30.

As shown in FIGS. 11-1 to 11-3, in a manufacturing method of semiconductor package 10 of the printed circuit board 51 and the carrier 80, providing a structure of the printed circuit board 51 and the carrier 80 are identical to those of FIG. 6. Secondly, a chip 20 and a conductive element 18 which is employed as a bump, wherein the chip 20 is employed as a flip chip and is electrically connected with the printed circuit board 51. Referring to FIG. 11-1, the chip 20 is arranged on the lower surface 42 of the insulator 40, and two ends of the conductive element 18 are electrically connected with the terminal 24 of the chip 20 and the trace 30 of the printed circuit board 51 respectively so that the chip 20 is electrically connected with the printed circuit board 51, and the third encapsulant 60 encapsulates the chip 20, the conductive element 18, and the printed circuit board 51, thus finishing the semiconductor package 10. Referring further to FIGS. 11-2, a removal process is provided, this removal process is for removing the carrier 80 away from the printed circuit board 51, the carrier 80 is eliminated in a mechanical grinding manner, a laser manner, a chemical etching and/or other removal manners so that the carrier 80 is removed from the printed circuit board 51, and the upper surface 91 of the dielectric layer 90 of the printed circuit board 51 exposes to the atmosphere. Preferably, the trace 30 is sealed by the dielectric layer 90 to avoid being corroded by the etching solution. Referring further to FIG. 11-3, a drilling process is provided, this drilling process is for the portion 90F being transferred to be a dielectric layer 90, the portion 90F of the dielectric layer 90 is eliminated so that the predetermined opening 9F is transferred to be the opening 96, and the terminal 3A of the trace 30 enables to be externally electrical connection, wherein the attached area 3A4 of the trace 30 is connected with the dielectric layer 90 so that the trace 30 is still coupled with the insulator 40 firmly, and no gap occurs between the upper surface 32 of the trace 30 and the insulator 40. Accordingly, the opening 96 of second dielectric layer 95 is formed in a laser manner or in a chemical etching manner and/or the like.

As shown in FIGS. 12-1 to 12-3, a method of manufacturing the semiconductor package 10. First, as illustrated in FIG. 12-1, structure of the printed circuit board 51 and a carrier 80 is provided, the structure of the printed circuit board 51 and the carrier 80 is identical to those of FIG. 7. Second, a chip 20 and a conductive element 18 are provided, the chip 20 is coupled with the printed circuit board 51. With reference to FIG. 12-1, the chip 20 is arranged on an upper surface 41 of the insulator 40, two ends of the conductive element 18 are electrically connected with the terminal 24 of the chip 20 and the trace 30 of the printed circuit board 51 individually so that the chip 20 is electrically connected with the printed circuit board 51, and the encapsulant 60 encapsulates the chip 20, the conductive element 18, and the printed circuit board 51, thus finishing the semiconductor package 10. Referring further to FIGS. 12-2 a drilling process is provided, this drilling process is for the predetermined opening 9F being transferred to be an opening 96, wherein the portion 90F of the dielectric layer 90 is eliminated so that the predetermined opening 9F is transferred to be the opening 96, and the terminal 3A of the trace 30 enables to be exposed to the opening 96 for externally electrical connection, wherein the protruded portion 99 of the dielectric layer 90 is between the opening 96 of the dielectric layer 90 and the side wall 85 of the opening 86 of the carrier 80, the protruded portion 99 of the dielectric layer 90 is accommodated in the opening 86 of the carrier 80, in this manner, the protruded portion 99 of the dielectric layer 90 is coupled with the side wall 85 of the opening 86. As shown in FIG. 12-3, due to the carrier 80 enables to be selectively served as a conductive element, such as copper, nickel or the like, and the side edge 83 of the carrier 80 is exposed to the atmosphere, therefore, a film 65 made of copper, nickel or the like material having electromagnetic shielding in an adhering manner, a coating manner or a sputtering manner and/or the like so that the film 65 is formed on the face 6S of the encapsulant 60, the side edge 53 of the printed circuit board 51, and the side edge 83 of the carrier 80, wherein the carrier 80 also enables to be used for electromagnetic shielding, wherein due to the film 65 enables to be coupled with the side edge 83 of the carrier 80 so as to enhance an area of the electromagnetic shielding of the semiconductor package 10 by using the carrier 80, thus increasing resistance against the electromagnetic interference. With reference to FIG. 12-3, the side edge 33 of the trace 30 enables to expose to the side edge 43 of the insulator 40 as required, and the trace 30 is connected with the film 65 to enhance utility of the printed circuit board 51. In addition, referring to FIGS. 12-1 and 12-2, the upper surface 81 of the carrier 80 also enables to be coupled with the second dielectric layer 95 (as shown in FIG. 7), wherein the second dielectric layer 95 is coupled with the upper surface 81 of the carrier 80 and the dielectric layer 90, and second dielectric layer 95 further has another carrier 8K as illustrated in FIG. 14-1, wherein the coupling layer 8C1 of the carrier 8K is connected with the second dielectric layer 95. In addition, an removal process is executed before forming the opening as shown in FIG. 12-2 so as to remove another carrier, then providing a drilling process, the second dielectric layer 95 has an opening after finishing the drilling process, and the opening of the second dielectric layer 95 corresponds to the opening 86 of the carrier 80, the opening 96 of the dielectric layer 90, and the terminal 3A of the trace 30. In addition, a solder ball S as shown in FIG. 12-3 enables to be provided in the method of manufacturing a semiconductor package 10, the solder ball S is coupled with both the terminal 3A of the trace 30 and the protruded portion 99 of the dielectric layer 90, wherein the solder ball S enables to be coupled with the carrier 80 optionally.

With reference to FIGS. 13-1 to 13-4 showing a method of manufacturing of the semiconductor package 10. Referring to in FIG. 13-1, a structure of the printed circuit board 51 and the carrier 80 is provided, the structure of the printed circuit board 50 and the carrier 80 is identical to that of FIG. 1-1, and a chip 20 and a conductive element 18 (such as a conductive bump) are provided, wherein the chip 20 is connected with the printed circuit board 51. As shown in FIG. 13-1, the chip 20 is arranged on an upper surface 32 of the trace 30, two ends of the conductive element 18 are connected with the terminal 24 of the chip 20 and the trace 30 respectively so that the chip 20 is electrically connected with the printed circuit board 51, and the encapsulant 60 encapsulates the chip 20, the conductive element 18, and the printed circuit board 51, thus finishing the semiconductor package 10. Referring further to FIGS. 13-2 and 13-3 showing a drilling process is provided, this drilling process is for the predetermined opening 9F being transferred to be an opening 96 and the carrier 80 being comprised of an opening individually, wherein this drilling process is comprised of a first drilling process and a second drilling process, an opening 96 is formed on the dielectric layer 90, and an opening 86 is formed on the carrier 80. As shown in FIG. 13-2, the carrier 80 has the opening 86, and the opening 86 has a side wall 85 and passes through the carrier 80, wherein the opening 86 corresponds to the predetermined opening 9F of the dielectric layer 90, such that the portion 90F of the dielectric layer 90 exposes to the opening 86.

As illustrated in FIG. 13-3 showing a second drilling process is provided, the dielectric layer 90 has the opening 96 passing through the dielectric layer 90 and corresponding to the terminal 3A of the trace 30, such that the terminal 3A of the trace 30 exposes to the opening 96 so as to be for externally electrical connection. The openings 86, 96 are formed in a laser manner, a chemical etching and/or other forming manners. It is to be noted the first drilling process (as shown in FIG. 13-2) is optional, i.e., only the second drilling is provided, accordingly, the dielectric layer 90, the carrier having an opening 96, 86 simultaneously, as illustrated in FIG. 13-3., thus enhancing production efficiency. The carrier 80 is made of metal, and a solder ball S (as shown in FIG. 10-5) enables to be coupled with the terminal 3A of the trace 30, wherein the solder ball Scan also be connected with the side wall 85 of the opening 86 and the upper surface 81 of the carrier 80 so that the carrier 80 is used as a grounding. With reference to FIG. 13-4, a film 65 is used for electromagnetic shielding, wherein the carrier 80 is made of metal and is used for electromagnetic shielding, and the film 65 is coupled with the face 6S of the encapsulant 60, the side edge of the printed circuit board 50 (i.e., the side edge of the dielectric layer 90), and the side edge 83 of the carrier 80 in an adhering manner, a coating manner, and/or other attaching manners. Thereby, an area of the electromagnetic shielding of the semiconductor package 10 is increased by way of the carrier 80 to enhance a resistance of the semiconductor package 10 against electromagnetic interference. Referring to FIG. 13-4, the side edge 33 of the trace 30 also enables to expose to the side edge of the encapsulant 60 so that the trace 30 is connected with the film 65, thus increasing utility of the printed circuit board 50.

The printed circuit boards 50, 51, and the carrier 80, 88 and the method of manufacturing the semiconductor package of above-mentioned embodiments are not limited the scope of the present invention. For example, any one printed circuit board 50, 51 of FIGS. 1-1 to 8 mates with any one carrier 80, 88 of FIGS. 1-1 to 8 or the carrier 8K of FIG. 9-1.

Thereby, the structure of the printed circuit board and the carrier is capable of reducing the thicknesses, material cost, and fabrication cost of the printed circuit board and the semiconductor package. Preferably, it is able to avoid gap or a removal between the lower surface of the trace and the insulator or the encapsulant and to enhance a quality of the printed circuit board.

Any one semiconductor package of FIGS. 9-1 to 13-4 matches with any one printed circuit board 50, 51 and/or any one carrier 80, 80, and 8K of FIGS. 1-1 to 11-4. Referring to FIGS. 10-1 to 10-2, forming the opening on the adjustment layer is increased or decreased to enhance the production efficiency or to reduce the fabrication cost.

The disclosed structure of the invention has not appeared in the prior art and features efficacy better than the prior structure which is construed to be a novel and creative invention, thereby filing the present application herein subject to the patent law.

What is claimed is:

1. A structure of a printed circuit board and a carrier,
the printed circuit board is for being coupled with at least one chip, wherein the printed circuit board is comprised of at least a trace and a dielectric layer, the trace having at least a terminal, the trace having an upper surface, a lower surface, and a side edge; the dielectric layer having a predetermined opening, an upper surface, a lower surface, and a side edge, wherein the predetermined opening is formed by a portion of the dielectric layer, the lower surface of the dielectric layer is coupled with the upper surface of the trace, in this manner, the upper surface of the trace is sealed by the dielectric layer entirely, and wherein the predetermined opening of the dielectric layer corresponds to the terminal of the trace; and
the carrier includes an upper surface, a lower surface, and a side edge, wherein the lower surface of the carrier is coupled with the upper surface of the dielectric layer, and the upper surface of the carrier exposes to atmosphere.

2. The structure as claimed in claim 1, wherein the trace further has an extending portion adjacent to the terminal so that the trace is comprised of the terminal and the extending portion, wherein the upper surface of the terminal is for externally electrical connection, and wherein the periphery of the trace is employed as an attached area.

3. The structure as claimed in claim 1, wherein the printed circuit board further includes an insulator, and the insulator includes an upper surface, a lower surface, a side edge, and a via, the insulator is coupled with the lower surface of the dielectric layer, and the insulator is also coupled with both the lower surface and the side edge of the trace, the via of the insulator corresponds to the lower surface of the trace, and the portion of the lower surface of the trace exposing to the via of the insulator is employed as a contact, and the contact of the trace is for externally electrical connection.

4. The structure as claimed in claim 3, wherein the printed circuit board further includes a second trace, and the second trace includes an upper surface, a lower surface, a side edge, and a protruded portion, wherein the protruded portion is formed on the lower surface of the second trace, and the lower surface of the second trace is coupled with the upper surface of the insulator so that the protruded portion is accommodated in the via of the insulator, and the second trace is electrically connected with the contact of the trace through the protruded portion of the second trace.

5. The structure as claimed in claim 1, wherein the carrier includes an adjustment layer and another carrier coupled with the adjustment layer, and a surface of the adjustment layer exposing to the atmosphere is employed as the upper surface of the carrier.

6. The structure as claimed in claim 5, wherein the adjustment layer includes a blind via corresponding to the trace, and the blind via of the adjustment layer has a width and a depth.

7. The structure as claimed in claim 1, wherein the carrier includes a plurality of elements which are a copper clad laminate, prepreg, and a detachable copper foil stacked together, wherein the copper clad laminate is comprised of two copper foils and an adhesive mean, wherein the adhesive mean is defined between the two copper foils; and wherein the detachable copper foil is comprised of two copper foils and a release layer, the release layer is connected with the two copper foils and is defined between the two copper foils, one of the two copper foils connected with the release layer is employed as a coupling layer, and another copper foil is employed as a detachable layer connected with the copper clad laminate by using the prepreg, and the carrier is connected with the dielectric layer by way of the coupling layer.

8. The structure as claimed in claim 7, wherein the coupling layer has a thickness, and the detachable layer has a thickness, wherein the thickness of the coupling layer is more than that of the detachable layer.

9. The structure as claimed in claim 1, wherein the carrier further includes an opening passing through the carrier, and the opening of the carrier having a side wall, the opening of the carrier corresponds to the predetermined opening of the dielectric layer and the terminal of the trace, wherein the dielectric layer further includes a protruded portion which is formed on the upper surface of the dielectric layer, in this manner, the protruded portion of the dielectric layer is between the predetermined opening of the dielectric layer and the side wall of the opening of the carrier, the protruded portion of the dielectric layer is accommodated in the opening of the carrier and coupled with the side wall of the opening.

10. The structure as claimed in claim 9 further comprising a second dielectric layer coupled with the upper surface of the carrier and the dielectric layer.

11. The structure as claimed in claim 10 further comprising another carrier, wherein said another carrier includes a plurality of elements which are a copper clad laminate, prepreg, and a detachable copper foil stacked together, wherein the copper clad laminate is comprised of two copper foils and an adhesive mean, wherein the adhesive mean is defined between the two copper foils; and wherein the detachable copper foil is comprised of two copper foils and a release layer, the release layer is connected with the two copper foils and is defined between the two copper foils, one of the two copper foils connected with the release layer is employed as a coupling layer, and another copper foil is employed as a detachable layer connected with the copper clad laminate by using the prepreg, and said another carrier is connected with the second dielectric layer by way of the coupling layer.

12. The structure as claimed in claim 11, wherein the coupling layer has a thickness and the detachable layer has a thickness, wherein the thickness of the coupling layer is more than that of the detachable layer.

13. The structure as claimed in claim 1, wherein the side edge of the trace is coupled with the dielectric layer, in this manner, both the lower surface and the side edge of the trace are coupled with the dielectric layer.

14. The structure as claimed in claim 13, wherein the printed circuit includes an insulator, and the insulator includes an upper surface, a lower surface, a side edge, and a via, the insulator is coupled with both the lower surface of the dielectric layer and the lower surface of the trace, wherein the via of the insulator corresponds to the lower surface of the trace, in this manner, a portion of the lower surface of the trace exposing to the via of the insulator is employed as the contact which is for externally electrical connection, and wherein the printed circuit board further includes a second trace which is for externally electrical connection, and the second trace includes an upper surface, a lower surface, a side edge, and a protruded portion, wherein the protruded portion is formed on the lower surface of the second trace, and the lower surface of the second trace is coupled with the upper surface of the insulator, so that the protruded portion of the second trace is accommodated in the via of the insulator and is electrically connected with the contact of the trace.

15. The structure as claimed in claim 13, wherein the trace of the printed circuit board comprises a protruded portion, the protruded portion is formed on the lower surface of the trace, and wherein the printed circuit board further comprises a second trace and an insulator, the second trace has a side edge, an upper surface, and a lower surface, wherein a portion of the lower surface of the second trace is employed as a contact which is for externally electrical connection, and the insulator includes an upper surface, a lower surface, and a via. the lower surface of the insulator is coupled with both the lower surface of the dielectric layer and the lower surface of the trace, wherein the second trace is situated on the upper surface of the insulator, and the insulator seals both the lower surface and the side edge of the second trace, wherein the upper surface of the second trace exposes to the upper surface of the insulator, and the contact of the second trace exposes to the via of the insulator, wherein the via of the insulator corresponds to the protruded portion of the trace, and the protruded portion of the trace is accommodated in the via, in this manner, the trace is electrically connected with the contact of the second trace.

16. The structure as claimed in claim 1 further comprising a film used for electromagnetic shielding, wherein the film is coupled with the side edge of the carrier and the side edge of the dielectric layer.

17. The structure as claimed in claim 1, wherein the carrier is made of metal.

18. The structure as claimed in claim 17, wherein the carrier is used for heat dissipation.

19. The structure as claimed in claim 17, wherein the carrier is used for externally electrical connection.

20. The structure as claimed in claim 1, wherein the carrier is used for electromagnetic shielding.
